(19) United States
(12) Patent Application Publication
(10) Pub. No.: US 2017/0355059 A1
(43) Pub. Date: Dec. 14, 2017

(54) Slurry Slip Stream Controller For CMP System

(71) Applicant: Confluense LLC, Furlong, PA (US)

(72) Inventor: Stephen J. Benner, Lansdale, PA (US)

(73) Assignee: Confluense LLC, Furlong, PA (US)

(21) Appl. No.: 15/622,627

(22) Filed: Jun. 14, 2017

Related U.S. Application Data
(60) Provisional application No. 62/349,956, filed on Jun. 14, 2016.

(51) Int. Cl. B24B 37/005; B24B 57/02; H01L 21/306; H01L 21/67; H01L 21/66

(52) U.S. Cl. CPC B24B 37/005; H01L 21/67253; H01L 22/26; H01L 21/6708; H01L 21/30625; B24B 57/02; H01L 21/67248

(57) ABSTRACT

A system for providing in situ analysis of the polishing slip stream during CMP processing is proposed. The system performs real-time measurement and then adjustment of necessary parameters (related to the slurry and/or the planarization process) to reduce process variation. In particular, the system enables the control of multiple process intensification techniques of CMP systems such as, but not limited to, slurry and chemical dispensing, pad vacuum “exhaust”, mass transfer techniques, heat transfer techniques, and mechanical adjustment techniques.

### CROSS REFERENCE TO RELATED APPLICATIONS

This application claims the benefit of U.S. Provisional Application Ser. No. 62/349,956, filed Jun. 14, 2016 and herein incorporated by reference.

### BACKGROUND OF THE INVENTION

In chemical mechanical planarization (CMP) processing, a semiconductor substrate is typically mounted on a rotating plate or other holder, and the surface of the substrate is brought into contact with a rotating polishing surface of a polishing pad in the presence of a colloidal polishing slurry. Non-planarities along the substrate surface, attributed to one or more semiconductor fabrication steps (e.g., underlying layers, patterns formed on the substrate, etc.) are then removed by creating relative motion under pressure between the substrate and the polishing pad, while providing a supply of one or more slurry compositions to the polishing surface of the polishing pad. The liquid/solid interfacial region is typically thin (for example, in the range of 10-40 μm) and at nominal velocities during polishing, shear rates of 10⁵-10⁷ s⁻¹ are not uncommon.

Depending on the materials being removed, a CMP process may be primarily mechanical (where the material removal is dominated by an abrasive action), or chemical (i.e., etching a portion of material from the substrate surface). Indeed, a typical CMP process may comprise a combination of mechanical and chemical removal, whereby chemical etching or softening action occurs due to one or more components of the slurry and mechanical abrasion or erosion is fostered between one or more of the solid materials involved (slurry solids, film solids, pad solids) by the mechanical action of the polisher. These interactions can be quite complex and subject to changing conditions (e.g., temperature, pressure, speeds, concentration, contaminants and the like) during the polishing step. For example, in the case of copper polishing, the process has been characterized as a temperature-activated, abrasion-assisted dissolution. This three body abrasion: (1) workpiece, (2) interfacial materials (liquid and solid), and (3) pad (contact and normal force component for friction) has been a topic of much research.

The particular slurry composition, as well as the parameters under which the CMP are conducted, will typically be a function of the particular characteristics of the various primary and secondary materials to be removed from the semiconductor substrate surface. In particular, in a case where a polysilicon layer pattern and a silicon oxide layer pattern are being polished using a silica-based slurry having SiO₂ as the primary abrasive, the removal rate of the polysilicon will tend to be higher than the removal rate of silicon oxide. Stabilizing and/or controlling the local removal characteristics requires discrete control of the chemical composition electro-chemical potential, solids concentration and morphology, liquid film attributes (e.g., temperature, viscosity, chemistry, thickness), and energy/work attributes (tool geometry which generates shear and normal components, pad mechanical properties, pad surface topography, bearing/contact area, substrate topography, surface tension, etc).

Although materials and equipment suppliers spend significant effort controlling the input state of their respective products, the prior art does not allow for the measurement and control of the changes/variation of the states occurring within the ‘slip stream’ throughout the polishing process. Indeed, typical mass transfer of CMP kinetic processes is measured in the range of μS to mS. Typical CMP removal rates vary from about 2 to 8 nanometers per second, and the budget for planarity is constantly shrinking with reduced feature sizes, requirements being less than 10 nm globally in advanced devices. Any type of ex situ or global process for controlling the various parameters that drive the CMP removal process is not sufficient, since various parameters such as heat, decay, agglomeration, entrainment, and the like, cannot be properly compensated during a polishing process that is about 30 to 180 seconds long.

### SUMMARY OF THE INVENTION

The need remaining in the prior art is addressed by the present invention, which relates to an in situ analysis of the polishing slip stream during CMP processing, performing real-time measurement and then adjustment of necessary parameters (related to the slurry, its flow field, and/or the mechanical planarization process) to reduce process variations. In particular, the system of the present invention enables the control of multiple process intensification techniques of CMP systems such as, but not limited to, slurry and chemical dispensing, pad vacuum “exhaust”, mass transfer techniques, heat transfer techniques, and mechanical adjustment techniques. Programmatic control of mass and energy equilibrium can be established and dynamically maintained throughout the wafer polishing process.

In accordance with one or more embodiments of the present invention, the system serves to control the energy input to the interfacial region so as to optimize and maintain its conversion efficiency. Through in situ direct or indirect measurement of state variables contained in the “spent” slip stream, the system of the present invention performs analysis, computation, and adjustments of the input parameters so as to offset any consumption-based shift away from desired values, center the corresponding outputs, and/or make adjustments intentionally shifting the energy or rate of the CMP process to “soft land” or de-tune the electrochemical selectivity. Additionally, the techniques of the present invention may be used for integrating new chemical surface treatments, as necessary. This closed loop method enables one to increase the process control frequency of the mass and energy transfer mechanisms by multiple orders of magnitude (e.g., 30×-200×) over the state of the art.

One exemplary embodiment of the present invention takes the form of a controller for use with chemical mechanical planarization (CMP) apparatus including at least a polishing head for supporting a semiconductor substrate over a polishing pad and a polishing slurry dispenser. The inventive controller is configured to comprise means for evacuating a portion of a slip stream from the proximity of a wafer during CMP processing and a slip stream evaluation system for receiving the evacuated slip stream and generating process control signals for the polishing head and the polishing slurry dispenser in response thereto so as to establish and maintain equilibrium during CMP processing.

Other and further aspects of the present invention will become apparent during the course of the following discussion and by reference to the accompanying drawings.

### BRIEF DESCRIPTION OF THE DRAWINGS

Referring now to the drawings, where like numerals represent like parts in several views:

FIG. 1 illustrates a conventional CMP apparatus and a slip stream control system of the present invention for use with the CMP apparatus;

FIG. 2 is a simplified diagram showing the movement of the slurry and slip stream with respect to a polishing pad and a wafer;

FIG. 3 is a database of exemplary state variables associated with the operation of the slip stream control system;

FIG. 4(a) shows the relative positions of a polishing pad and wafer, as well as the location where the polishing slurry is introduced into the system;

FIG. 4(b) illustrates the changes in temperature of the slurry as a function of time;

FIG. 5 is a graph of increase in CMP process temperature as a function of time; and

FIG. 6 is a photograph of a typical temperature gradient created during CMP processing.

### DESCRIPTION OF THE INVENTION

The colloidal chemistry of a polishing slurry used in CMP processing is characterized by a slurry manufacturer. Typically, a slurry is mixed in bulk by combining abrasive particles and additives, oxidizers, etchants, complexants and/or de-ionized water to a suspension agent. Likewise the elastomeric, porosity, macro and microstructure of the polishing pads used in CMP apparatus are characterized by their manufacturer. Pads are “conditioned” whereby the surface texture is abrasively machined to create a texture and asperity profile whose surface roughness and bearing area establish the contact and lubrication “slip stream” between the pad body and wafer surface. The present invention is directed to monitoring these attributes of the slurry and pads as they are consumed in the polishing process, by measuring and analyzing the constituents in the slip stream of material exiting from between the wafer and pad during processing. The measurements and analyses are then used to adjust and/or control the material removal rate, planarity, and defects in a timely manner such that the CMP apparatus is able to arrive at and maintain an equilibrium process condition through bulk removal, and tuned to land softly at polishing end point, be more selective in dissimilar material workpieces, and surface treat/inhibit galvanic or environmental corrosion.

The state variables measured in the inventive process can include, but are not limited to, “spent” polishing slurry (e.g., pH drifts, concentration, temperature rise, slurry viscosity), complexants, process liquids, pad qualities (e.g., temperature, hardness, abrasion, erosion, thickness), wafer qualities (e.g., abrasion, erosion, thickness), mass and morphology, pad bearing and contact area, residence time, composition of products (including by-products and transients), and temperature. By integrating the in-feed material (e.g., concentration, feed rate, feed position, solids, temperature, and the like) and mechanical conditions (e.g., relative speed and pressure of the polishing head, slip stream exhaust location, slip stream measurement location, exhaust flow rate, pad starting thickness), the process and system of the present invention is able to intensify, optimize and control the energy within the wafer/pad interface throughout the entire polishing operation; all three-body abrasion conditions are able to be controlled.

As mentioned above, the system of the present invention provides the ability to control mass transfer techniques (such as, but not limited to, slurry dispensing, chemical dispensing, additional, dilution, slip stream volume removed/pad vacuum), heat transfer techniques (e.g., heating or cooling of slurry, heating or cooling of the platen, liquid removal, friction) and mechanical adjustment techniques (such as, but not limited to, pressure, speed, shear and mixing). The closed loop system of the present invention is useful with simple, single material systems by reducing the state variation seen by the workpiece (i.e., wafer). Additionally, the closed loop system of the present invention is useful in more complex two- and three-material systems with patterned surfaces and requiring disparate material polishes or steps, where varying input parameters are required to manage the process at the workpiece surface (e.g., managing multiple slurries, pressures/speeds, material selectivity, zeta potential, inter-step cleaning, and the like).

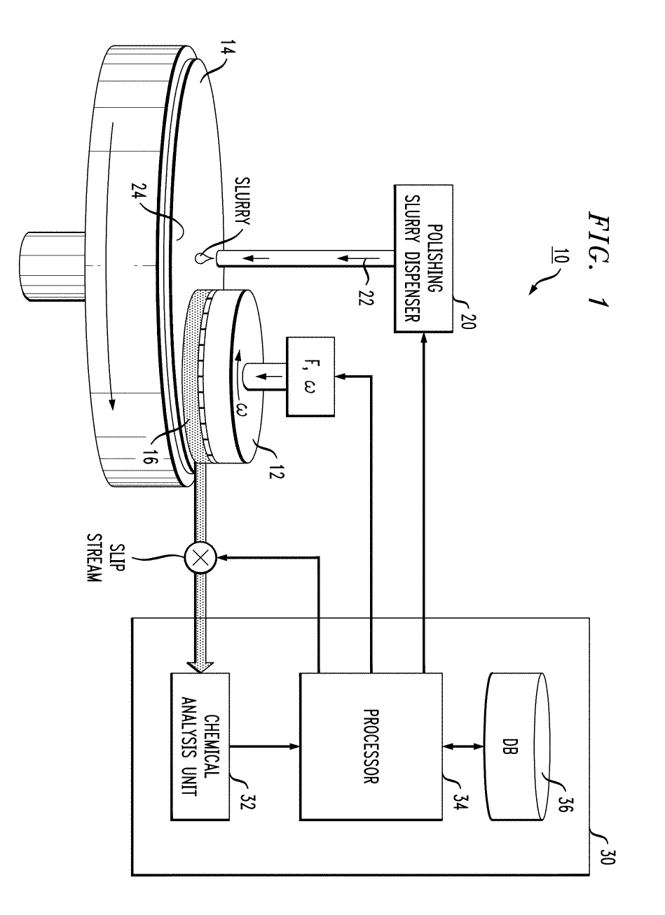

FIG. 1 illustrates an exemplary CMP apparatus 10 that may be used to monitor both the colloidal states of the processed slurry and the removal rate of the material being polished, and thereafter modify the residence time of the ‘slip stream’ in response to the kinetic conversion and decay, or change the state of the polishing materials and the resulting removal rate of the workpiece for improved output conditions. As shown, a polishing head 12 is positioned above a polishing pad 14 of CMP system 10. A semiconductor wafer 16 is attached to the bottom surface of polishing head 12 and is thereafter lowered onto the (rotating) polishing pad 14 to initiate a conventional wafer planarization process. In this example, semiconductor wafer 16 is shown as comprising a thick layer that may be, for example, a dielectric material or a metal (such as copper). Indeed, “layer” may comprise a stack of layers of different materials—dielectrics, metals, “barrier layers”, trench linings, and the like.

A polishing slurry dispenser 20 is used to introduce fresh polishing slurry 22 of a predetermined composition onto surface 24 of polishing pad 14, where polishing slurry 22 includes materials that contribute to the planarization process. That is, the polishing slurry may comprise certain chemical additives that will etch away or soften exposed areas of layer. An abrasive particulate material of a predetermined size and solids concentration may be included in the slurry and used to grind away portions of the top layer (or, alternatively, cohesively bond in the case of Ceria to function as a ‘chemical tooth’, pulling out atoms of silicon from the surface). Abrasive-free electrolytes (for eCMP processes), or other types of abrasive-free chemical slurries may also be used.

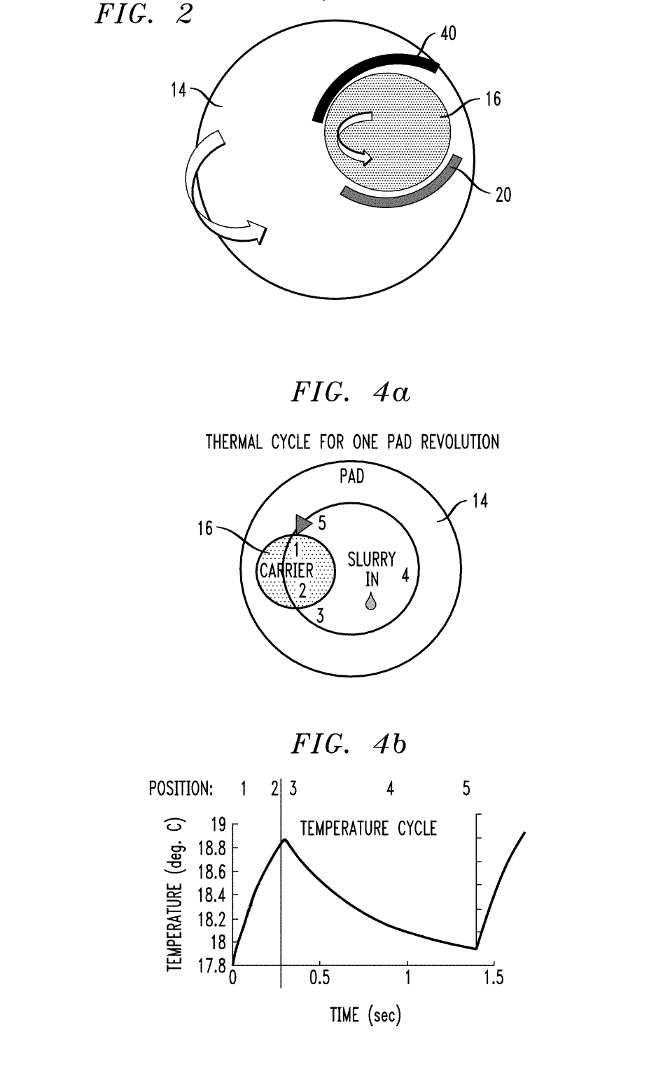

In accordance with one or more embodiments of the present invention, CMP apparatus 10 also includes a slip stream evaluation system 30 that is utilized to evacuate the removed wafer material, pad debris and spent slurry as it exits from under the wafer and thereafter analyze the components found in the slip stream to better control the wafer planarization process. FIG. 2 is a simplified diagram showing the elements involved in the analysis, particularly polishing pad 14 and wafer 16 in accordance with one embodiment of the present invention. The configuration as shown in FIG. 2 positions slurry dispenser 20 immediately upstream of the position of wafer 16 (and is configured to maintain its relative position with respect to wafer 16). Slurry dispenser 20 is formed to exhibit an arc-like form, providing the ability to radially control the dispensing of the slurry, or provide any type of zoned or swept application of the polishing slurry, by controlling a plurality of separate ports (not shown) within dispenser 20. Slip stream exhaust path element 30 is shown as disposed immediately behind the backside of wafer 16.

In this particular configuration, therefore, an intense, aggressive polishing process is possible, with the slurry introduced immediately in the vicinity of the wafer, passing once underneath the wafer, and then extracted via exhaust path element 40, which is configured as an arc-like element (for example), to improve and control the extraction process. Inasmuch as current processes typically use a single-port slurry dispenser located at a position removed from the wafer itself (such as shown in the embodiment of FIG. 1), it has been found that as much as 90% of the dispensed slurry never contributes to the wafer polishing process and is caught up in the bow wave, which runs around the wafer carrier without entering the interfacial space before exiting the apparatus. The contained, compact configuration of FIG. 2 is considered to improve the efficiency of the process, while also able to immediately react to changes in the MCR and MRR and modify the slurry dispensing process, as necessary.

It is to be understood that one parameter to be controlled in accordance with the present invention is the volume of slip stream that is removed as a function of time. The removal is vacuum-assisted and may be radially adjustable by the user to allow for different volumes to be collected as dictated by the particular planarization process, gradient heat or flow field effects, state of the polishing pad and composition of the slurry.

Referring back to FIG. 1, the slip stream exhaust is separated from the air stream and presented to evaluation system 30 that is used to measure the current state of the removed colloid. The removed material (both solids and liquids) is passed through a chemical analysis unit 32 to determine the current “material change rate” (MCR) associated with the planarization process. All components being transformed by the process can be analyzed, including (but not limited to) slurry chemicals and abrasives, abraded pad particles and radial wear, solid or dissolved wafer film materials. The ability to also determine, in real time, the wafer's material removal rate (MRR) can be accomplished by other means and is well-known in the art and is used for various purposes including, for example, end point detection of the removal process. Unlike the ability to measure and monitor MCR in real time in accordance with the present invention, the determination of the wafer MRR typically requires a larger process window.

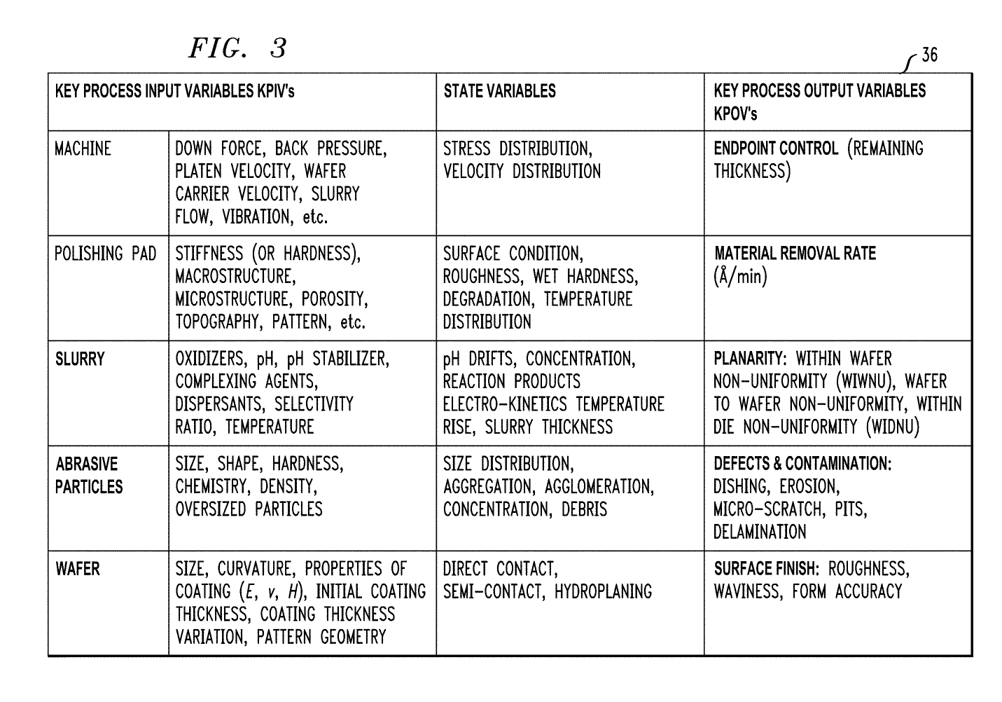

In accordance with the present invention, the measured, current values of the MCR and MRR are then used to adjust (if necessary) the residence time/radial position of the polishing material on the pad which controls the amount of decay/variation contained therein. Evaluation system 30 monitors the applicable state variables via an included processor 34, which compares the current values to input attributes stored in an associated database 36. FIG. 3 illustrates an exemplary collection of information that may be stored in database 36.

Based on configurable process-specific kinetic models, processor 34 provides signal adjustments to CMP apparatus 10 to adjust, for example, the residence time and conditioning set points at all radial positions, throughout the operation. These various adjustments may include, but are not limited to, slurry dispensing quantity, temperature and/or location, conditioning abrasive speed and downforce, vacuum setpoint, slip stream exhaust rate, cleaning/heat transfer/complexant feed rates, etc. In accordance with the principles of the present invention, evaluation system 30 functions to counteract various process gradients that occur in real time (e.g., temperature changes, electrochemical potential changes, concentration changes, debris composition changes, and the like), as well as purposeful adjustment to soft land or compensate for gradient effects, or affect material selectivity or potential at process endpoint. In particular, processor 34 compares the current value of the MCR to desired values (i.e., input attributes) and then determines if any adjustments in slurry residence are required.

If the residence of the slurry or cleaner needs to be increased, a “+” control signal is sent to reduce the vacuum level within CMP apparatus (perhaps associated within a conditioning head, not shown). Similarly, if the residence time needs to be decreased, a “−” control signal is sent to increase the vacuum level (for example, the sweep profile of an associated conditioning apparatus may be altered to evacuate the surface area more quickly, or evacuate the center, slower-moving re-entrainment regions more aggressively). The analysis may also indicate changes required to downforce (shown as F on FIG. 1) due to pad particle ‘adders/concentration’ achieving an unacceptable control level or in response to pad temperature/wet hardness changes. Rinse, corrosion inhibitors or selectivity complexant dispensing signals can be provided by evaluation system 30 to alter the removal rate, electro-kinetic potential and/or wafer end state.

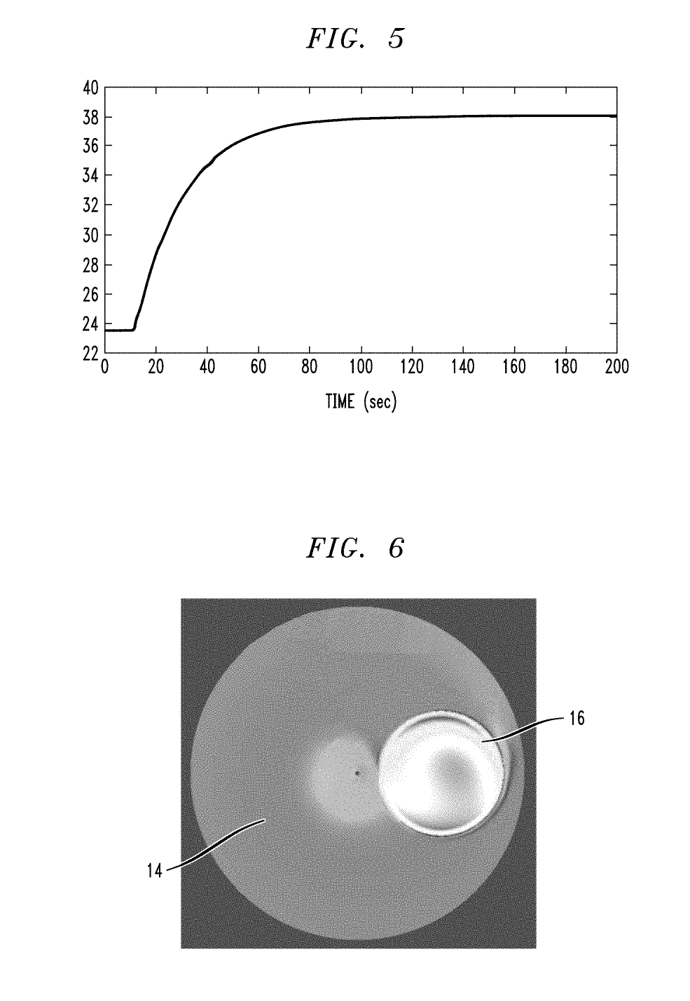

In addition to residence time at any given location on the polishing pad, analysis unit 30 of the present invention may also be used to control the slip stream heat removal rate by adjusting the volume of the liquid extracted (and fresh slurry supplied), as well as signal separate heat transfer tooling to respond to temperature measurements that are outside of desired ranges. FIGS. 4(a) and 4(b) illustrate a typical heating cycle at a particular radial location within a copper CMP process. FIG. 4(a) shows the relative positions of pad 14 and wafer 16, as well as the location where the polishing slurry is introduced into the system. The rotation of wafer 16 with respect to pad 14 is also shown. FIG. 4(b) illustrates the changes in temperature as a function of time, associated with position in the cycle, with “1” being the far-side of wafer 16, “2” being the near-side of wafer 16, etc. As shown, the temperature is highest at this leading edge position 2 of wafer 16. Over time, heat energy continues to increase during a typical CMP process, as shown by the graph of FIG. 5. And FIG. 6 is a photograph of typical temperature gradients that are created during a planarization process. The increase in temperature at the interface between the wafer and polishing pad (particularly on the “leading edge” of the wafer) are clearly shown.

By measuring the temperature of the slip stream material while evacuating the spent slurry from the pad surface, the radially localized “heating/cooling rate” at the interface between the wafer and the pad can be intensified and maintained with significantly improved uniformity, controlling the replenishment slurry temperature, co-located with the evacuation produces a consistent activation temperature and balanced energy for copper oxidation and/or dissolution, throughout the polish duration, resulting in both improved removal rate and uniformity. Changes in speed, pressure (friction heating), chemical concentration (reaction kinetics), material flows (energy in and out) and solids, as well as their effect on the process, can all be accommodated by a slip stream control system formed in accordance with the present invention.

The process of slip stream monitoring is considered on-going, with analysis unit 30 utilized in a continuous manner to constantly adjust/fine-tune the removal characteristics of the slip stream in order to best control the material removal rate, planarity and defects of the CMP apparatus.

Prior attempts at analyzing CMP processes utilized a more global approach, applying area flow averaging for example, that was unable to monitor real-time system changes. In accordance with the present invention, the use of continuous analysis of the MCR values is able to institute near-rear-time changes in process parameters that allow the CMP process to achieve and maintain equilibrium conditions and improve the overall wafer planarization.

Summarizing, the analysis system of the present invention enables a process equilibrium to be optimized and dynamically maintained throughout the wafer planarization process. Through adjustments of replenishment slurry temperature, relative speed and pressure determine the energy input, slurry exhaust location, exhaust flow rate, rinse or surface treatment flows determine energy transported from the interface.

It is to be understood that the above-described embodiments are illustrative of only a few of the many possible specific embodiments that can represent applications of the principles of the present invention. Numerous and varied other arrangements can be made by those skilled in the art without departing from the spirit and scope of the present invention as defined by the claims appended hereto.

What is claimed is:

1. A controller for use with chemical mechanical planarization (CMP) apparatus including at least a polishing head for supporting a semiconductor substrate over a polishing pad and a polishing slurry dispenser, the controller comprising:
means for evacuating a portion of a slip stream from the proximity of a wafer during CMP processing; and
a slip stream evaluation system for receiving the evacuated slip stream and generating process control signals for the polishing head and the polishing slurry dispenser in response thereto so as to establish and maintain equilibrium during CMP processing.

2. The controller as defined in claim 1 wherein the slip stream evaluation system comprises
a chemical analysis unit for measuring a current value of the material change rate (MCR) of the evacuated slip stream components;
a database storing preferred values of a plurality of predetermined models and state variables; and
a processor for determining current values of the plurality of predetermined state variables from the current value of the MCR, comparing the current values to the preferred values stored in the database, and generating CMP process control signals based on the comparison.

3. The controller as defined in claim 2 wherein the CMP process control signals include signals transmitted to the polishing slurry dispenser.

4. The controller as defined in claim 2 wherein the control signals transmitted to the polishing slurry dispenser provide control for parameters selected from the group consisting of: slurry volume, slurry composition, slurry temperature, and slurry dispensing location.

5. The controller as defined in claim 2 wherein the control signals transmitted to the apparatus provides control for parameters selected from the group consisting of: residence time, polishing head—zone downforce, conditioning abrasive downforce, and speed-rotation.

6. The controller as defined in claim 2 wherein the control signals transmitted to the CMP apparatus provide control for slip stream exhaust, and associated with parameters selected from the group consisting of: vacuum pressure, location of slip stream removal, removal volume.

7. The controller as defined in claim 1 wherein the CMP apparatus comprises a multi-port slurry dispenser disposed immediately upstream of the polishing head, with process control signals from the slip stream evaluation system used to control radial application of slurry with respect to a wafer, including zoned slurry applications and sweeping slurry applications.

8. The controller as defined in claim 7 wherein the multi-port slurry dispenser exhibits an arc-like geometry to correspond to the curved edge of the wafer.

9. The controller as defined in claim 7 wherein the means for evacuating a portion of the slip stream comprises a slip stream extraction element disposed immediately downstream of the polishing head such that slurry dispensed by the multi-port slurry dispenser makes a single pass underneath the wafer and thereafter enters the slip stream extraction element.

10. The controller as defined in claim 9 wherein the slip stream extraction element exhibits an arc-like geometry to correspond to the curved edge of the wafer.

11. A method of controlling a chemical mechanical planarization (CMP) process to planarize an irregular surface of a semiconductor wafer, the method comprises the steps of:
a) creating a database of optimal values for all state variables that contribute to the CMP process for a number of different material systems, including disparate materials along a surface of the semiconductor wafer;
b) extracting at least a portion of a slip stream of material used in the CMP process;
c) measuring current values of state variables found in the slip stream material;
d) comparing the measured values to the optimal values contained in the database; and
e) adjusting the CMP process, as necessary, to maintain current state variable values within a predetermined range of the optimal values.

12. The method as defined in claim 11, wherein the adjusting step includes adjusting one or more attributes of the polishing slurry used in the CMP process.

13. The method as defined in claim 12, where the slurry attributes include at least slurry composition, slurry temperature, slurry additions, dilution, and agglomeration.

14. The method as defined in claim 11, wherein the adjusting step includes adjusting one or more attributes of the slip stream extraction step.

15. The method as defined in claim 14, where the slip stream extraction attributes include at least a volume of slip stream material removed as a function of time, slip stream extraction location, vacuum control of extraction.

16. The method as defined in claim 11, wherein the adjusting step includes adjusting one or more attributes of the CMP apparatus.

17. The method as defined in claim 16, wherein the CMP apparatus attributes include at least a downforce applied to the wafer, a velocity of the polishing pad, a velocity of the polishing head.
